(19) United States
(12) Patent Application Publication
(10) Pub. No.: US 2013/0134998 A1
(43) Pub. Date: May 30, 2013

(54) POWER LINE VOLTAGE MEASUREMENT USING A DISTRIBUTED RESISTANCE CONDUCTOR

(71) Applicants: Frederick J. Kiko, Carlsbad, CA (US); Gregory M. Nulty, Reston, VA (US)

(72) Inventors: Frederick J. Kiko, Carlsbad, CA (US); Gregory M. Nulty, Reston, VA (US)

(73) Assignee: Tollgrade Communications, Inc., Cranberry Twp., PA (US)

(21) Appl. No.: 13/690,591

(22) Filed: Nov. 30, 2012

Related U.S. Application Data
(60) Provisional application No. 61/565,087, filed on Nov. 30, 2011.

(51) Int. Cl. H01C 13/02; H01C 1/00; H01C 7/00; G01R 27/02

(52) U.S. Cl. CPC H01C 13/02; G01R 27/02; H01C 1/00; H01C 7/00
USPC 324/705; 338/333; 338/214

(57) ABSTRACT

A system for measuring electrical properties of a power line comprising a first wire and a second wire. The system comprises a sensor unit configured for connection to the first wire; and an elongated resistive element comprising a first end configured for connection to the sensor unit and a second end configured for connection to the second wire, the elongated resistive element having a distributed resistance. The first wire may be a hot wire and the second wire may be a hot wire or a neutral wire.

### CROSS-REFERENCE TO RELATED APPLICATIONS

The present application claims the benefit under 35 U.S.C. §119(e) of U.S. Provisional Application Ser. No. 61/565,087, filed on Nov. 30, 2011, titled “Power Line Voltage Measurement Using Distributed Resistance Conductor,” which is hereby incorporated by reference in its entirety.

### BACKGROUND

Power lines are widely used in many settings to carry 50 Hz or 60 Hz alternating current to power the worldwide economy. They form an important part of the power distribution system, carrying power from generation facilities all the way to the locations where it is used. The power distribution system may include many types of power lines with high voltage lines used closer to the power generation facilities and lower voltage lines closer to the locations where the power is used such as homes and businesses, for example.

A power company may desire to obtain accurate voltage measurements of power lines in the power distribution system in order to manage and maintain the power lines. For example, voltage measurements may be used to manage voltage levels and amount of reactive power throughout the power distribution system (e.g., by using the measured voltage to determine how to operate switched capacitor banks and/or other components of a power distribution system). As another example, voltage measurements may be used to detect power theft. As yet another example, voltage measurements may be used to detect faults in the power distribution system.

Conventional approaches to measuring voltage of a high voltage power line involve using metal (e.g., copper) wire(s) or potential transformers (PT) to electrically couple a voltage sensor to a voltage carrying (i.e., “hot”) wire of the power line and a neutral wire of the power line in order to measure the voltage between the voltage-carrying wire and the neutral wire.

### SUMMARY

Improved power line management is facilitated through a system that accurately measures electrical properties of high voltage power lines in a power distribution system. The system comprises one or more sensor units coupled to the power lines by using one or more resistive elements having a distributed resistance. A resistive element having a distributed resistance may have a high resistance along its length such that if the resistive element were to sustain damage (e.g., by breaking, sagging, stretching, breaking away from the wire to which it is coupled, etc.), the risk of large voltages causing high currents through the resistive element and endangering the surrounding environment (e.g., utility crews, pedestrians, equipment, buildings, etc.) is reduced, even if the resistive element were to come in contact with an object in the environment.

To obtain a voltage measurement of a high-voltage power line, in some embodiments, a sensor unit may be attached to a voltage-carrying wire (i.e., a phase) of a power line and may further be coupled to another wire (e.g., neutral wire or a phase) of the power line via a resistive element having a distributed resistance. The sensor unit may be configured to measure one or multiple electrical properties of a voltage-carrying wire including, but not limited to, voltage, current, harmonics, disturbances, relative phase angle, and power factor. For example, the sensor unit may obtain a voltage measurement of the power line by measuring the voltage between the voltage-carrying wire and the neutral wire, measuring a current flow through the resistive element, and adjusting the measured voltage for the voltage drop across the resistive element based on the measured current flow and the resistance of the resistive element.

Accordingly, some embodiments are directed to a system for measuring electrical properties of a power line comprising a first wire and a second wire. The system comprises a sensor unit configured for connection to the first wire and an elongated resistive element comprising a first end configured for connection to the sensor unit and a second end configured for connection to the second wire, the elongated resistive element having a distributed resistance.

Other embodiments are directed to a resistive element adapted for connecting a sensor unit between a first wire and a second wire of a power line. The resistive element comprises an elongated member having a length of at least 3 feet, the elongated member having a first end and a second end, wherein the elongated member has an average resistance of at least 1 MOhm/foot and a resistance distribution variation of less than +/−40% between any two 12 inch segments of the elongated member.

Still other embodiments are directed to a method of operating a sensor unit coupled to power line, the power line comprising at least a hot wire carrying in excess of 1,000 volts and another wire. The method comprises measuring a voltage between the hot wire and the other wire with a voltage sensor in the sensor unit, measuring a current flow through a resistive element connected in series with the sensor unit between the hot wire and the other wire, and adjusting the voltage measurement based on the measured current through the resistive element.

The foregoing is a non-limiting summary of the invention, which is defined by the attached claims.

### BRIEF DESCRIPTION OF DRAWINGS

The accompanying drawings are not intended to be drawn to scale. In the drawings, each identical or nearly identical component that is illustrated in various figures is represented by a like numeral. For purposes of clarity, not every component may be labeled in every drawing. In the drawings:

FIG. 1 is an illustration of a three-phase power line “WYE” circuit in which embodiments of the disclosure provided herein may operate.

FIG. 2 illustrates one type of resistive element having a distributed resistance, in accordance with some embodiments of the disclosure provided herein.

FIGS. 3A-3B illustrate another type of resistive element having a distributed resistance, in accordance with some embodiments of the disclosure provided herein.

FIG. 3C illustrates yet another type of resistive element having a distributed resistance, in accordance with some embodiments of the disclosure provided herein.

FIG. 4 illustrates a sensor unit configured to sense electrical properties of a three-phase power line in a “WYE” circuit, in accordance with some embodiments of the disclosure provided herein.

FIG. 5 is an illustration of a three-phase power line “DELTA” circuit in which embodiments of the disclosure provided herein may operate.

FIG. 6 illustrates a sensor unit configured to sense electrical properties of a three-phase power line in a “DELTA” circuit, in accordance with some embodiments of the disclosure provided herein.

FIGS. 7A and 7B illustrate alternate embodiments of techniques for measuring voltage in a system using a resistive element.

FIG. 8 is a sketch of an exemplary technique for manufacturing a distributed resistive element having a tap near its end.

### DETAILED DESCRIPTION

The inventors have recognized that improvements to the safety and simplicity of installation of sensor units in a power distribution system may, in addition to providing other benefits, increase the likelihood that such sensors will be deployed. With more widespread deployment, there is greater opportunity for benefits of monitoring of the power distribution systems. The inventors have recognized that improvements to safety and simplicity of installation may be achieved by using an element with distributed resistance to connect the sensor unit between wires of a power line. These improvements may allow for the installation of the sensor unit even when the power line is “hot.” Such an approach may also provide an increased ability to find faults in the power distribution system rapidly.

In a conventional approach using a metal wire to electrically couple a voltage sensor between two wires of a power line, if the connector were to become damaged by breaking (e.g., into two or more segments), the segment of the broken metal connector would be “hot.” This dangling metal segment could pose a risk to the surrounding environment including to utility crews, pedestrians, and other equipment. In contrast, when a distributed resistive element is used, the longer the resistive conductor segment is (thereby posing a risk of arcing and/or contact with other elements), the more resistive it will be. Accordingly, the possible current flow, and thus associated risk, is reduced.

The inventors have also recognized that using a resistive element having a distributed resistance, to electrically couple a sensor unit between two wires of a power line may simplify installation of the sensor unit. In some embodiments, the sensor may be connected to the power line while power is flowing. Making such a connection might be undesirable using a metal wire.

Accordingly, in some embodiments a system for measuring electrical properties of a power line (e.g., a high or medium voltage power line) in a power distribution system is disclosed. The power line may have a plurality of voltage-carrying wires (e.g., three voltage-carrying wires in a three-phase line) and, in some embodiments, may also have a neutral wire. The system may comprise a sensor unit electrically coupled to a wire of the power line and an elongated resistive element having a distributed resistance and electrically coupling the sensor unit to another wire of the power line (e.g., another voltage-carrying wire or the neutral wire). In this configuration, the sensor unit may obtain voltage, current, and/or any other electrical measurements of the wire to which it is attached. A medium voltage power line may be a power line carrying less than approximately 50 KVolts. A high voltage power line may be a power line carrying greater than approximately 50 KVolts.

In some embodiments, the resistive element having a distributed resistance may comprise a plastic/carbon fiber extrusion formed by doping or coating plastic (e.g., fiber made of plastic) with carbon or other elements or compounds to produce a uniform, high resistance material. Though, in other embodiments, conductive ink may be used. The plastic/carbon fiber extrusion may form a resistive core of the distributed resistive element and may be insulated by a protective (e.g., insulative) jacket.

In some embodiments, the resistive element having a distributed resistance may comprise a substrate comprising conductive traces and having a plurality of discrete resistors connected in series and attached to the conductive traces. The resistive element may be flexible, rigid, or be at least partially flexible and at least partially rigid. For example, in some embodiments, the resistive element may comprise a plurality of segments including at least one flexible segment and at least one rigid segment.

In some embodiments, a high voltage power line may carry at least 1,000 volts. In some embodiments, a high voltage power line may carry between 5,000 and 15,000 volts. In some embodiments, a high voltage power line may carry at least 5,000 volts, at least 10,000 volts, 25,000 volts, at least 50,000 volts, at least 100,000 volts, at least 250,000 volts, or at least 500,000 volts. As a specific example, a resistive element may be configured to span wires that differ in voltage by approximately 70,000 volts. It should be appreciated that a high voltage power line may carry any other suitable voltage or a range of voltage, as aspects of the disclosure provided herein are not limited in this respect.

It should be appreciated that the embodiments described herein may be implemented in any of numerous ways. Examples of specific implementations are provided below for illustrative purposes only. It should be appreciated that these embodiments and the features/capabilities provided may be used individually, all together, or in any combination of two or more, as the application is not limited in this respect.

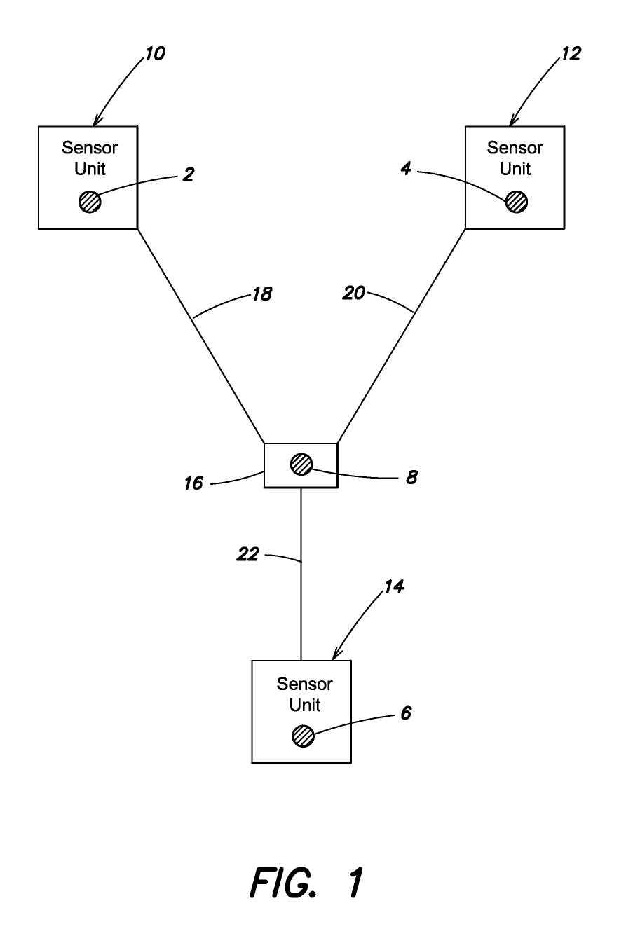

FIG. 1 illustrates one environment in which embodiments of the disclosure provided herein may operate. In particular, FIG. 1 shows an illustrative WYE three-phase power line circuit comprising wires 2, 4, and 6 for conducting three-phase power and a neutral or ground wire 8. Attached to each wire 2, 4, and 6 is a corresponding sensor unit 10, 12, and 14 respectively. A sensor unit may be attached to a wire mechanically, for example by using clamps, conductive adhesives or any other suitable mechanisms, as aspects of the disclosure provided herein are not limited in this respect. In the illustrated embodiment a different sensor unit is attached to each of the three voltage-conducting wires, but in other embodiments sensor units may be attached to each of two or all three of the wires in a three-phase power line. In some embodiments, a sensor unit may be attached to only some wires in a power line such that there may be one or multiple voltage-carrying wires in the power line to which no sensor unit is attached. For example, in a three-phase power line a sensor unit may be attached only to one of three or only two of three voltage-carrying wires.

Sensor units 10, 12, and 14 are electrically coupled to neutral wire 8 via resistive elements 18, 20, and 22, respectively. In particular, resistive element 18 runs between sensor unit 10 and neutral wire 8, resistive element 20 runs between sensor unit 12 and neutral wire 8, and resistive element 22 runs between sensor unit 14 and neutral wire 16. Resistive elements 18, 20, and 22 are mechanically coupled to neutral wire 8 using clamp 16, though other mechanical means may be used to couple one or more resistive elements to a neutral wire, as aspects of the disclosure provided herein are not limited in this respect. In addition, though a single clamp is shown in the embodiments of FIG. 1, it should be appreciated that FIG. 1 schematically illustrates the connections. In some embodiments, multiple clamps (and/or other mechanical means) may be used to attach resistive elements to a neutral wire. For example, each resistive element may be attached with a separate clamp.

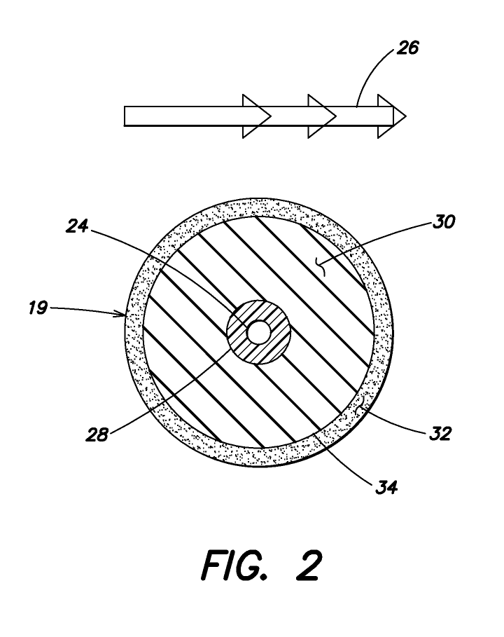

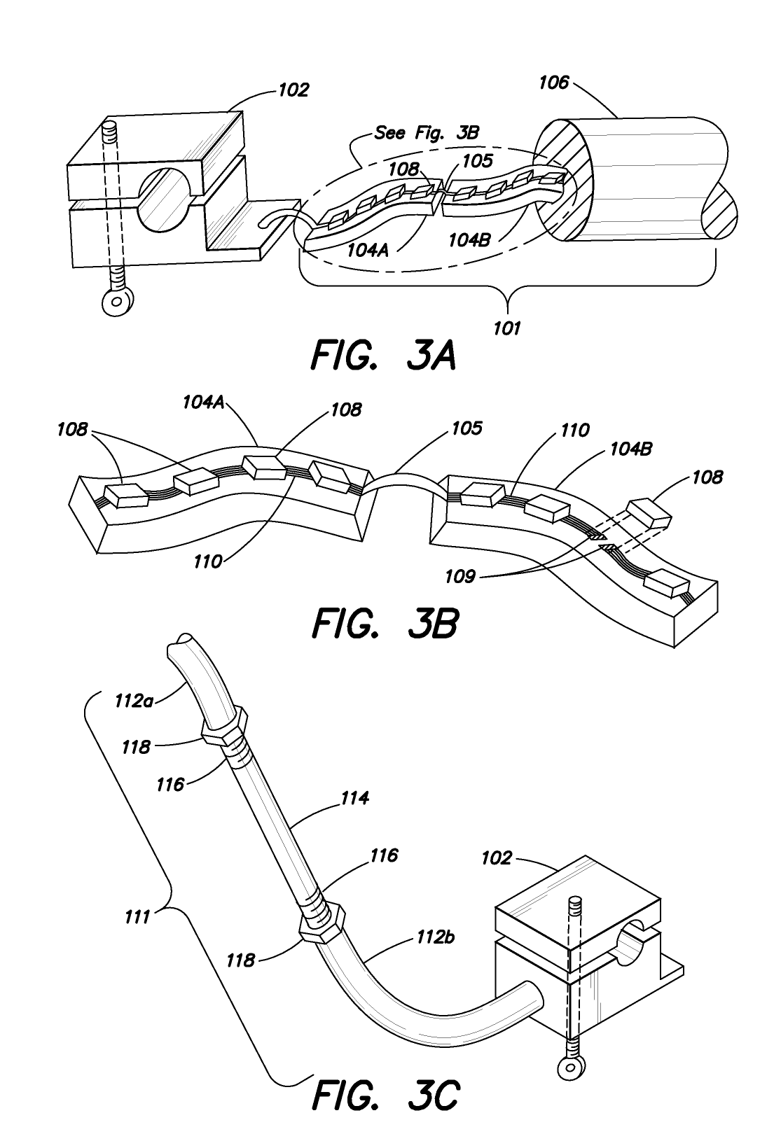

Each of resistive elements 18, 20, and 22 may have a distributed resistance. Each of resistive elements 18, 20, and 22 may be of any suitable type of resistive element having a distributed resistance, illustrative examples of which are described below with reference to FIGS. 2 and 3A-3C. In some embodiments, each of resistive elements 18, 20, and 22 is the same type of resistive element. In other embodiments, two or all three of the resistive elements 18, 20, and 22 are different types of resistive elements.

A resistive element having a distributed resistance (e.g., resistive elements 18, 20, and 22) and may have any suitable length to connect a sensor unit to another wire (e.g., neutral wire 8, FIG. 1). For example, a resistive element may be at least two feet long, at least three feet long, at least four feet long, at least five feet long, at least six feet long, at least ten feet long, at least twenty feet long, or may be any other suitable length needed to connect the sensor unit to another wire.

A resistive element having a distributed resistance (e.g., elements 18, 20, and 22) may be constructed to provide any suitable amount of resistance per a unit (e.g., a foot, a meter, multiple feet, multiple meters) of its length. The amount of resistance per unit length may depend on the distance and voltage between wires to be spanned by the resistive element. Further, the resistive element may reflect a tradeoff between power consumption and accuracy of voltage measurements. A resistive element having a higher resistance may be one for which a sensor unit obtains lower accuracy voltage measurements. On the other hand, a resistive element having a lower resistance and allowing for higher accuracy voltage measurements dissipates more power. In some embodiments, the resistance per unit length can be determined, and for a resistive element with a given length and a given voltage between wires to be spanned by the resistive element, to provide a measurable signal of less than a target value of volts (e.g., less than 10 volts, less than 5 volts, less than 2.5 volts, or less than 1.25 volts in some embodiments), and with a power dissipation of less than a target value, which for example may be 100 watts or less, 50 watts or less, 35 watts or less, 25 watts or less, or watts or less. For example, in some embodiments, a resistive element may have a distributed resistance of at least 0.5 MOhm/foot, at least 1 MOhm/foot, at least 3 MOhm/foot, at least 5 MOhm/foot, at least 10 MOhm/foot, at least 15 MOhm/foot, etc. In its entirety, a resistive element may provide for a resistance of at least 10 MOhms, at least 20 MOhms, at least 30 MOhms, at least 50 MOhms, at least 75 MOhms, or any other suitable resistance, as aspects of the disclosure provided herein are not limited in this respect.

In some embodiments, the distributed resistance of a resistive element may be uniform along its length such that any segment of a given length will have the same resistance as any other segment of the same length. Though, it is not a requirement that the distributed resistance be uniform. In some embodiments, variations in manufacturability may result in variations in resistance along the length of the resistive element. Alternatively or additionally, the resistive element may contain segments for flexibility or to provide desirable mechanical properties that are not resistive or that have different resistive properties than the bulk of the resistive element. Accordingly, in some embodiments, the distributed resistance of a resistive element may vary along the length of the element. For example, the distributed resistance of any one 12 inch segment of the resistive element may vary by no more (i.e., less) than a certain percentage of the distributed resistance of any other 12 inch segment of the resistive element. For instance, the distributed resistance of any segment may vary by less than 10%, by less than 25%, by less than 40%, by less than 50% from the distributed resistance of any other segment of the resistive element of 12 inches or other comparable length.

A resistive element having a distributed resistance (e.g., elements 18, 20, and 22) may be constructed so as to dissipate a small amount of power along its length. For example, in some embodiments, the resistive element connecting two wires (e.g., conducting wire 2 and neutral wire 8 as shown in FIG. 1) of a power line carrying a voltage of at least 35K Volts may dissipate less than 25 Watts.

A resistive element having a distributed resistance may be constructed to have any of the above-described properties (e.g., resistivity properties, power dissipation properties, length, etc.) in any of numerous ways, illustrative examples of which are described below.

One type of resistive element having a distributed resistance is illustrated in FIG. 2, which shows a cross-section of resistive element 19 having a distributed resistance. The cross-section of resistive element 19 includes a central hole 24 configured to receive a pin 26 that is utilized for centering resistive element 19. A high resistance extrusion 28 surrounds central hole 24. Extrusion 28 may be formed in any suitable way and, in some embodiments, may be a plastic/carbon fiber extrusion formed by doping the core of a fiber or plastic with carbon or other elements or compounds. One end of extrusion 28 may be electrically coupled to a sensor unit (e.g., sensor unit 10, 12, or 14) and the other end of extrusion 28 may be electrically coupled to another wire (e.g., neutral wire 8 or another voltage-carrying wire having a different phase than the wire to which the sensor unit is coupled). As shown in FIG. 2, resistive element 19 has central hole 24, but in other embodiments a resistive element may not have a central hole, as aspects of the disclosure provided herein are not limited in this respect.

Resistive element 19 further comprises high voltage dielectric 30 surrounding extrusion 28 and an insulative sheath 32 surrounding dielectric 30. Insulative sheath 32 may be configured to avoid moisture and sunlight from passing therethrough, potentially compromising the internal construction of resistive element 19. In some embodiments, resistive element 19 may comprise fiberglass 34 in place of or in addition to dielectric 30 to avoid stretching of resistive element 19 in use.

The extrusion 28 may have any suitable distributed resistance. For example, in some embodiments, extrusion may have a distributed resistance of at least 0.5 MOhm/foot, at least 1 MOhm/foot, at least 3 MOhm/foot, at least 5 MOhm/foot, at least 10 MOhm/foot, at least 15 MOhm/foot, 50 MOhms/5 feet, or any other suitable distributed resistance.

Another type of resistive element having a distributed resistance is illustrated in FIGS. 3A-3B, which show the structure of resistive element 101 having a distributed resistance, with suitable resistive characteristics, which may be as described in connection with other embodiments. Resistive element 101 comprises flexible substrate 104 enclosed by an insulative sheath 106. Flexible substrate 104 may be formed of any suitable material having a high resistance such as thin printed circuit board segments, plastic or any suitable high-resistance polymer, including KAPTON or other material used in the manufacture of flexible circuit assemblies. Insulative sheath 106 may be configured to protect flexible substrate 104 and any elements disposed thereon (e.g., from moisture, sunlight, etc.) and may be constructed in any suitable way, as aspects of the disclosure provided herein are not limited in this respect.

Resistive element 101 comprises multiple discrete resistors 108 disposed on flexible substrate 104. Resistive element 101 further comprises conductive traces 110 disposed on flexible substrate 104 between resistors 108. Conductive traces 110 and resistors 108 may provide for a resistive path extending along the length of resistive element 101. Conductive traces 110 allow resistive element 101 to electrically couple to a sensor unit, which may be attached to a hot wire of a power line (e.g., sensor unit 10), to another wire of the power line such as a neutral wire (e.g., wire 8) or another wire of the power line carrying current at a different phase from the hot wire to which the sensor unit may be attached (e.g., wire 4 or 6). Conductive traces 110 may be coupled to a wire of a power line in any suitable way and, for example, may be coupled (e.g., soldered) or may be connected through a connector to a clamp attached to the wire. As shown in FIG. 3A, for example, conductive traces 110 are coupled to clamp 102.

Conductive traces 110 may be formed in any suitable way using any suitable conductive (e.g., at least partially carbon and/or at least partially metallic) or partially conductive material. In some embodiments, conductive traces 110 may comprise a layer of at least partially conductive ink disposed on flexible substrate 104. In some embodiments, a layer of partially conductive ink may provide sufficient resistance distributed along the length of resistive element 101.

As previously mentioned conductive traces 110 and resistors 108 may provide for a resistive path. This may be done in any suitable way. For example, a resistive path may be created by using the conductive traces to connect resistors in series. In the illustrated embodiment, conductive traces 110 comprise multiple non-contiguous segments used to connect resistors 108 is series. The resistors 108 are surface mount resistors attached (e.g., soldered) to the segments of conductive traces 110. For example, as shown in FIG. 3B, resistor 108 is in contact with ends 109 of adjacent segments of conductive traces 110, thereby coupling the two adjacent segments of conductive traces 110.

In some embodiments, flexible substrate 104 may comprise a plurality of segments, each segment having a resistive path provided thereon. Two segments 104a and 104b of flexible substrate 104 are illustrated in FIGS. 3A and 3B, though it should be appreciated that flexible substrate 104 may comprise any suitable number of segments. Each of segments 104a and 104b is illustrated as having a resistive path formed of four surface mount resistors 108 connected in series by segments of conductive traces 110. Though, each segment of flexible substrate 104 may have any other suitable number of resistors (e.g., two, three, five, six, seven, eight, nine, at least ten, at least twenty, etc.), as aspects of the disclosure provided herein are not limited in this respect. Segments of flexible substrate 104 (e.g., segments 104a, 104b, etc.) may be electrically coupled (e.g., via a conductive jumper or in any other suitable way) to form a resistive path along the length of flexible substrate 104. In the illustrated embodiment, segments 104a and 104b are coupled via conductive jumper 105. In some embodiments, a resistive path may comprise a number (e.g., seven) of resistors per unit length (e.g., an inch) and a jumper loop wire. This may provide for maximum copper wire gap between jumpers and may allow for higher power handling capability.

It should be appreciated that FIGS. 3A and 3B are not drawn to scale. However, to provide a sense of scale applicable in some embodiments, resistors 108 may be 1206 surface mount resistors. Substrate 104 may have a width comparable to the width of such resistors and a thickness less than the thickness of such resistors.

Resistors 108 may be connected in series, as previously described, thereby providing resistive element 101 with a distributed resistance. Resistors 108 may be spaced regularly or irregularly. In some embodiments, resistors 108 may be spaced such that the average pitch (i.e., center-to-center spacing between neighboring resistors) is less than a particular distance (e.g., less than 1 inch, less than 0.75 inch, less than 0.5 inch, less than 0.25 inch, less than 0.1 inch, less than 0.05 inch, etc.).

In some embodiments, for example, the resistors may be spaced to provide 4 or 5 resistors per inch. Each resistor 108 may have any suitable resistance. For example, a resistor 108 may have a resistance of at least 50 KOhms, 100 KOhms, of at least 200 KOhms, of at least 250 KOhms, of at least 300 KOhms, of at least 500 KOhms, of at least 750 KOhms, of at least 1 MOhm, etc. Resistors 108 may comprise resistors of different types and having different resistivity, as aspects of the disclosure provided herein are not limited to using resistors of the same type and resistivity. It should be appreciated that only four resistors are shown in FIG. 3A for clarity and that any suitable number of resistors (e.g., at least 5, at least 10, at least 20, at least 25, at least 50, at least 100, etc.) may be attached to the flexible substrate 104.

In the embodiment illustrated in FIGS. 3A and 3B, the resistive element may comprise a flexible portion, with clamps at each end for connection to wires. Though, other construction techniques are possible. For example, the resistive element may be terminated by using screw on sealed connectors. Another construction technique for a resistive element having a distributed resistance is illustrated in FIG. 3C, which shows resistive element 111 having a distributed resistance. As shown, resistive element 111 comprises multiple segments, some or all of which may be rigid. Though, having at least some of the segments be flexible may simplify installation and/or increase the ability to withstand damage from environmental forces such as wind. FIG. 3C illustrates segments including bent segment 112a coupled in series with straight segment 114 that is coupled in series with bent segment 112b. As shown, bent segments 112a and 112b are coupled to straight segment 114 via threaded coupling 116, and are secured via nuts 118. Though, any other suitable means may be used to coupling segments of a resistive element, as aspects of the disclosure provided herein are not limited in this respect. FIG. 3C shows a resistive element having three sections, but this is a non-limiting and illustrative example, as a resistive element may comprise any suitable number of sections (e.g., one, two, four, five, six, etc.).

Each section of resistive element 111 may be rigid or flexible. In the embodiments illustrated in FIG. 3C, for example, straight segment 114 may be rigid and bent segments 112a and 112b may be flexible to make it easier to couple resistive element 111 to wires of a power line. Alternatively or additionally, the segments of resistive element 111 may be provided as part of a kit adapted for connection between specific types of wires. In such a scenario, the dimensions and angles required to connect a sensor unit between wires of a power line may be known in advance and the components of the kit may be pre-configured with appropriate lengths and bend angles.

As shown, bent segment 112b couples resistive element 111 to clamp 102, which is configured to be attached to a wire of a power line. In some embodiments, all sections of resistive element 111 may be flexible, all sections of resistive element 111 may be rigid, or resistive element 111 may comprise any suitable number of rigid and flexible segments.

Resistive element 111 may be constructed to have a distributed resistance in any of numerous ways, including using any of the techniques described herein. In some embodiments, some or all of the segments of resistive element 111 may comprise a substrate having disposed thereon conductive traces with multiple resistors attached to the conductive traces in order to provide resistive element 111 with a distributed resistance. The substrate may be flexible and, in some embodiments, the segments of resistive element 111 may comprise a flexible substrate like flexible substrate 104 described above with reference to FIGS. 3A and 3B. In other embodiments, segments of resistive element 111 may comprise a high-resistance core (e.g., plastic doped with carbon) or may be constructed in any other suitable way.

Though, other techniques may alternatively or additionally be used to form resistive elements, including incorporating conductive fillers or dopants other than carbon into a matrix material, such as a plastic. Whether such a material is doped or made resistive with a filler, the matrix material may be rigid or made flexible, such as through the inclusion of plasticizers or using other techniques. Accordingly, it should be appreciated that any resistive element (e.g., resistive elements 18 and 101 described with reference to FIG. 2 and FIGS. 3A-3B, respectively) may comprise one or multiple sections and each of said sections may be flexible or rigid.

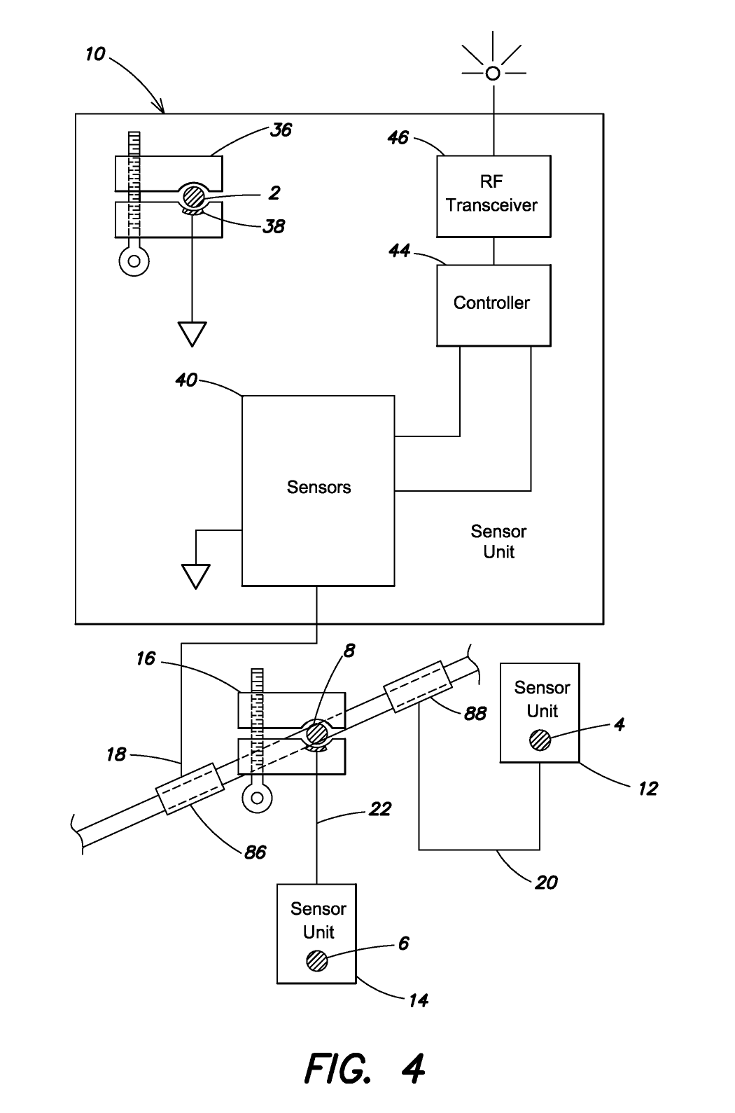

FIG. 4 illustrates sensor units configured to measure electrical properties of a three-phase power line in a “WYE” circuit. In particular, FIG. 4 illustrates components of sensor unit 10 described above with reference to FIG. 1. Sensor unit 10 comprises a clamp 36 for attaching the sensor unit to a power line wire (e.g., wire 2). Clamp 36 comprises contact 38 for making contact with the wire when clamp 36 is clamped about the wire. In high voltage power lines, each conducting wire may not be insulated. Accordingly, contact 38 may be in direct contact with the wire, when clamp 36 is attached to the wire.

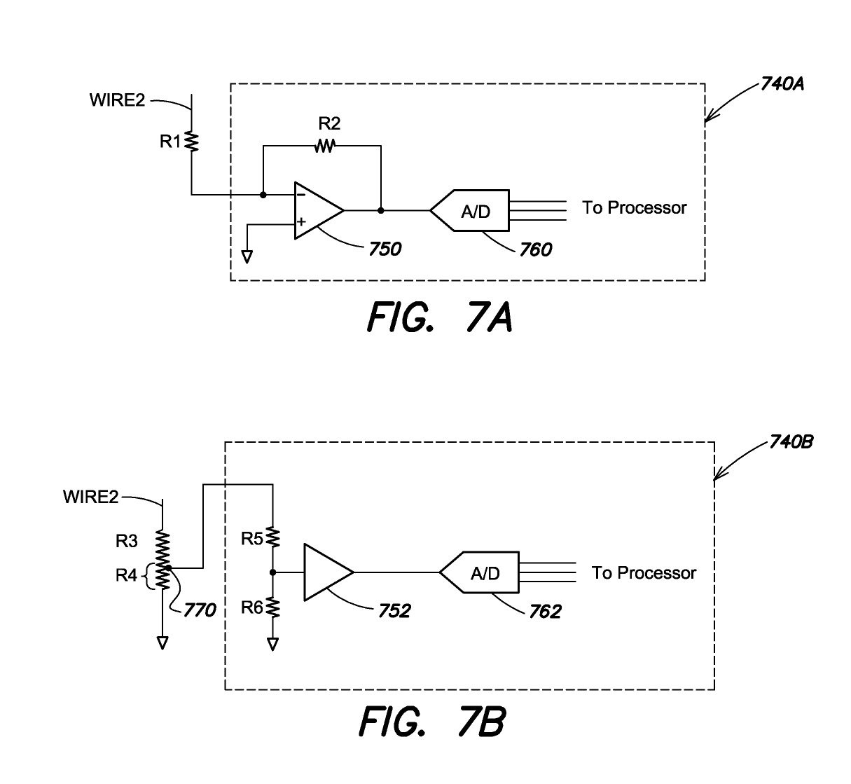

Sensor unit 10 further comprises sensors 40, which are electrically coupled to contact 38 by virtue of contact 38 establishing a common reference potential within sensor unit 10. Sensors 40 may be directly connected to wire 2 through a contact (e.g., contact 38) or may be indirectly coupled to wire 2 using techniques known in the art. In some embodiments, voltage sensors may be directly connected and current sensors may be indirectly connected. Sensors 40 are also coupled to resistive element 18. In operation, sensors 40 are configured to measure at least the voltage between contact 38, which is contact with wire 2 and acts a common reference for measurements within sensor unit 10, and the voltage at a location on resistive element18. As shown in FIG. 4, an end of resistive element 18 is connected to wire 8 via clamp 86. Accordingly, this voltage measurement may be related to the voltage between wire 2 and neutral wire 8. In some embodiments, sensors 40 may also include a current sensor, which may be coupled (directly or indirectly) to wire 2 and/or configured to measure current through resistive element 18. Any suitable measurement circuitry within sensors 40 may be used to relate a measured voltage within sensor unit 10 to the voltage between wires 2 and 8. Illustrative examples of suitable measurement circuitry are provided below in connection with FIGS. 7A and 7B.

In the embodiment illustrated, sensors 40 are connected to controller 44. Controller 44 is configured to calculate a voltage drop between wire 2 and neutral wire 8 based at least in part on the measurements obtained by sensors 40.

Accordingly, it should be appreciated that a sensor unit (e.g., sensor unit 10) may be operated to measure electrical properties (e.g., voltage, waveforms, harmonics, disturbances, relative phase angle, power factor) of a hot wire of a high-voltage power line (e.g., a power line carrying in excess of 10 KVolts). The process of operating the sensor unit may include using the voltage sensor in the sensor unit to measure a voltage between the hot wire and the neutral wire of the high voltage power line

Sensor unit 10 further comprises RF transceiver 46 that may be used to transmit voltage measurements (e.g., voltage measurements calculated by controller 44) to one or more collection nodes (not shown) configured to receive voltage measurements from multiple sensor units deployed in a power distribution system. The collection node(s) may be configured to process the received voltage measurements and perform one or more functions (e.g., detect power theft, determine how to control voltage and/or reactive power in the power management system, provide notification of a recommended action to an operator, etc.). Sensor units 12 and 14 may be configured in a manner similar to sensor unit 10 or may be configured in any other suitable way.

These sensor units may make corresponding measurements of other wires of the power distribution system. In the embodiment illustrated in FIG. 4, sensor unit 12 is attached to wire 4 and coupled to neutral wire 8 via resistive element 20 having distributed resistance and clamp 88. Accordingly, sensor unit 12 may measure properties on wire 4, which may be a hot wire. Sensor unit 14 is attached to wire 6 and coupled to neutral wire 8 via resistive element 22 and clamp 16. Accordingly, sensor unit 14 may measure properties of wire 6, which may be a hot wire.

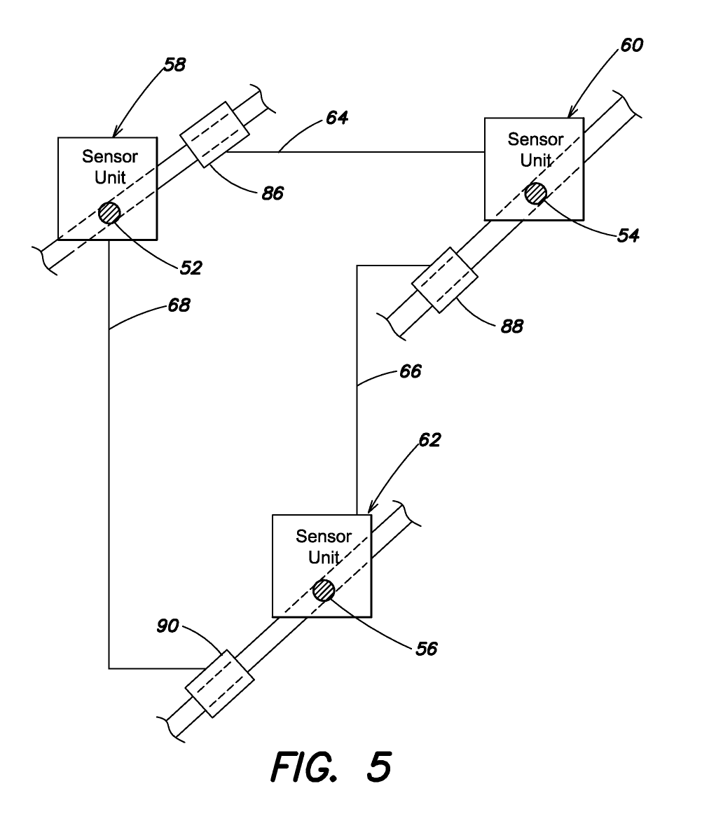

FIG. 5 illustrates another environment in which embodiments of the disclosure provided herein may operate. In particular, FIG. 5 shows an illustrative “DELTA” three-phase power line circuit comprising wires 52, 54, and 56 for conducting three-phase power. Attached (e.g., clamped) to each wire 52, 54, and 56 is a corresponding sensor unit 58, 60, and 62 respectively. Each of sensor units 52, 54, and 56 is electrically coupled to two voltage-carrying wires of the power line. As shown, sensor unit 58 is attached and electrically coupled to wire 52 and is also electrically coupled to wire 56 by resistive element 68. Accordingly, one end of resistive element 68 may be coupled to sensor unit 58, and the other and may be connected, such as through a clamp 90 to wire 56.

Sensor unit 60 is attached and electrically coupled to wire 54 and is also electrically coupled to wire 52 by resistive element 64. Sensor unit 62 is attached and electrically coupled to wire 56 and is also electrically coupled to wire 60 by resistive element 66. One end of each resistive element 64 and 66 may be connected, such as through a clamp 86 or 88 to a respective wire.

Each of resistive elements 64, 66, and 68 may have a distributed resistance. Each of resistive elements 64, 66, and 68 may be of any suitable type of resistive element having a distributed resistance, illustrative examples of which have been described with reference to FIGS. 2 and 3A-3C. In some embodiments, each of resistive elements 64, 66, and 68 is the same type of resistive element. In other embodiments, two or all three of the resistive elements 64, 66, and 68 are different types of resistive elements.

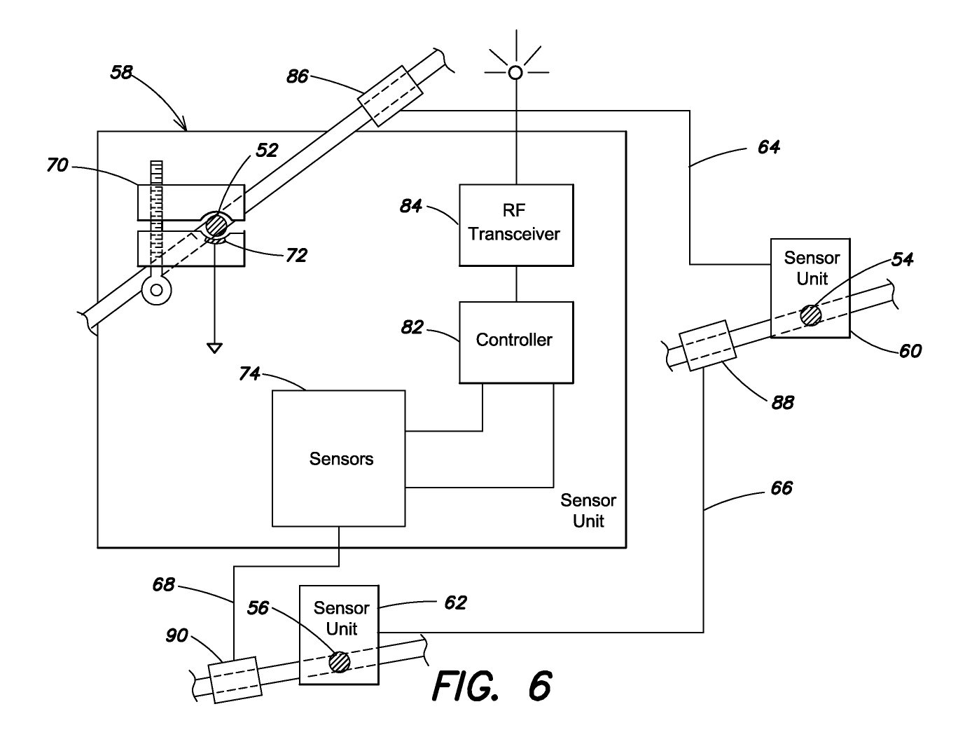

FIG. 6 illustrates a sensor unit configured to sense electrical properties of a three-phase power line in a “DELTA” circuit. In particular, FIG. 6 illustrates components of sensor unit 58 described above with reference to FIG. 5. In some embodiments, sensor unit 58 may have the same structure as sensor unit 10 (FIG. 4).

In the embodiment illustrated, sensor unit 58 comprises a clamp 70 for attaching the sensor unit to a power line wire (e.g., wire 52). Clamp 70 comprises contact 72 for making contact with wire 52 when clamp 70 is clamped about the wire 52. Sensor unit 58 further comprises sensors 74 configured for use in measuring voltage between wire 52 and wire 56. In some embodiments, sensors 74 may include a current sensor, a voltage sensor, and/or other sensors.

In the embodiment illustrated, sensor unit 58 comprises controller 82 and sensors 74 are connected to controller 82. Controller 82 is configured to calculate a voltage drop between wire 52 and wire 56 based at least in part on the measurements obtained by sensors 74.

Accordingly, it should be appreciated that a sensor unit (e.g., sensor unit 58) may be operated to measure electrical properties (e.g., voltage) of a hot wire of a high-voltage power line (e.g., a power line carrying in excess of 10 KVolts). The process of operating the sensor unit may include using the voltage sensor in the sensor unit to measure a voltage between the hot wire and another hot wire (corresponding to a different phase) of the high voltage power line. In some embodiments, the process of operating the sensor unit further comprises installing the sensor unit by attaching the sensor unit to a hot wire of the high-voltage power line, while the hot wire is carrying current.

Sensor unit 58 further comprises RF transceiver 84 that may be used to transmit voltage values (e.g., voltage measurements calculated by controller 82) to one or more collection nodes (not shown) configured to receive voltage values from multiple sensor units deployed in a power distribution system. Sensor units 60 and 62 may be configured in a manner similar to sensor unit 58 or may be configured in any other suitable way.

FIGS. 7A and 7B schematically illustrate measurement circuitry for measuring a voltage between wires of a power line using a resistive element as described herein. FIG. 7 illustrates measurement circuitry 740A, which may represent voltage measurement circuitry forming a portion of sensors 40 (FIG. 4) or sensors 74 (FIG. 6).

In the embodiment illustrated, measurement circuitry 740A includes an operational amplifier 750. Operational amplifier 750 is connected in a negative feedback configuration through a resistor R2 coupling its output terminal to its negative input terminal. The positive input terminal of operational amplifier 750 is coupled to the common voltage, which may be the voltage of the wire to which the measurement unit containing measurement circuitry 740A is attached.

FIG. 7A shows that the negative input terminal operational amplifier 750 is also coupled to a second wire, WIRE2, through a resistor R1. Resistor R1 may represent a distributed resistive element, examples of which have been described, such as resistive elements 18, 22, or 24 (FIG. 4) or resistive elements 64, 66 or 68 (FIG. 6).

The output of operational amplifier 750 is coupled to A/D converter 760. The output of A/D converter 716 is in turn coupled to a processor. That processor, for example, may be a controller of a sensor unit, such as controller 44 (FIG. 4) or controller 82 (FIG. 6). As a result of this connection, the processor may use the value at the output of operational amplifier 750 in computing the voltage between WIRE2 and the wire to which the sensor unit is attached.

In the configuration shown in FIG. 7A, the output of operational amplifier 750 may depend on the voltage on WIRE2 with respect to the common voltage to which operational amplifier 750 is referenced and the ratio of the values of resistors R1 and R2. The processor processing the output of operational amplifier 750 may be programmed with or may access computer storage locations storing information representing the values of resistors R1 and R2. In embodiments in which the computation is formed based on the ratio of the values of resistors R1 and R2, information about the values of those resistors may be stored as a ratio. Though, information about the values of the resistors stored in any suitable form, as aspects of the disclosure provided herein are not limited in this respect.

In some embodiments, the resistor R2 may be a precision resistor such that the value of resistor R2 may be determined from the rated values of the components used for resistor R2. Similarly, the resistive element represented by resistor R1 may be a precision resistor. For example, a resistive element manufactured using the techniques described with reference to FIGS. 3A and 3B may have a value that can be determined based on the construction of the resistive element. Accordingly, in some embodiments, information about the values of resistors R1 and R2 may be determined from rated values of the components use to construct the resistors. In other embodiments, values of the resistors, or the ratio of the resistors may be measured.

Regardless of how information about the values resistors R1 and R2 is determined, a processor receiving the output of A/D converter 760 may use this information to convert the output of operational amplifier 750 to a value representing the line voltage to be measured. In the embodiment illustrated, this computation may entail applying a known formula for the gain of an operational amplifier, in the configuration of operational amplifier 750. By scaling the measured value by the inverse of the gain, the line voltage may be computed.

In the embodiment illustrated in FIG. 7A, the value of resistor R2 may be small (e.g., smaller or much smaller) in comparison to the value of resistor R1. A small value may lead to a gain that is much less than 1. A specific value may be chosen so that the output of operational amplifier 750 does not saturate either operational amplifier 750 or A/D converter 760 at voltage levels expected on WIRE 2. For example, the value of resistor R1 may be on the order of 50 MOhms and the value of R2 may be on the order of a few KOhms, depending on the expected voltage to be measured on WIRE 2.

FIG. 7B illustrates an alternative embodiment of measurement circuitry that may be used in a sensor unit as described herein. FIG. 7B illustrates measurement circuitry 740B. As with measurement circuitry 740A, measurement circuitry 740B makes a measurement relative to a common voltage, which may be established by a wire, WIRE1, of a power line. In the embodiments illustrated in FIGS. 4 through 6, that common voltage is established by the wire to which a sensor unit containing the measurement circuitry is attached. Though, it should be appreciated that the common voltage may be established in any other suitable way.

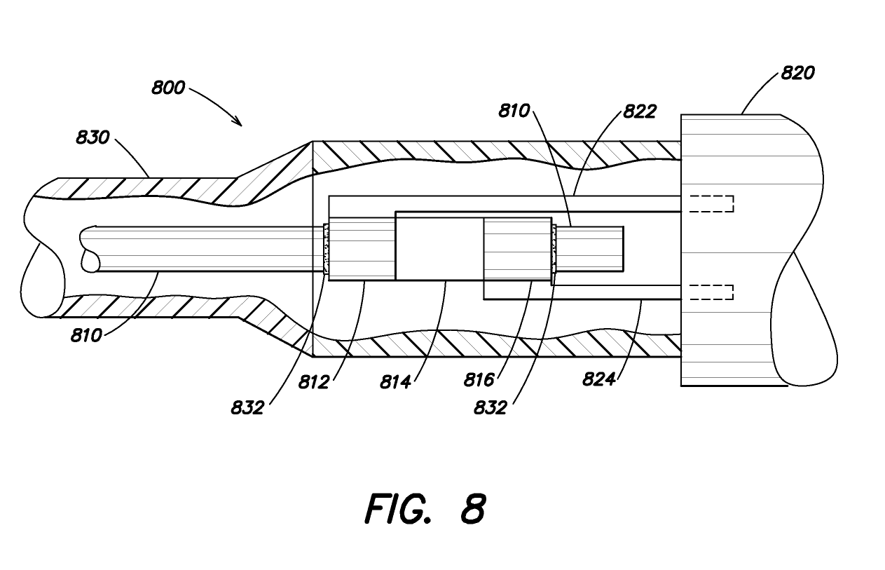

Measurement circuitry 740B, like measurement circuitry 740A, is connected to a distributed resistive element spanning to a wire, WIRE2, of a power line. The distributed resistive elements may be fabricated using techniques as described herein or in any other suitable way. In the example given in FIG. 7B, the distributed resistive element has a tap near one end. FIG. 8 provides an example of a construction technique suitable for forming a distributed resistive element with a tap.

Regardless of the manner in which the distributed resistive element is formed, FIG. 7B illustrates that the resistive element is divided by tap 770 into two portions, a first portion represented by resistor R3 and a second portion represented by resistor R4. The end of the resistive element adjacent resistor R4 is coupled to the common reference potential. The end of the resistive element adjacent resistor R3 is coupled to WIRE2. This configuration creates a resistive voltage divider at tap 770 in which the voltage at tap 770 depends on the ratio of resistors R3 and R4 and the voltage difference between WIRE2 and the common reference potential.

In some embodiments, tap 770 may be placed sufficiently close to the end of the resistive element that resistor R4 is a very small relative to resistor R3. In such a configuration, the voltage at tap 770 may be small, even when the voltage difference between WIRE2 and the common reference potential is large. If the voltage at tap 770 is small enough to measure without saturating components within measurement circuitry 740B, that voltage may be measured, digitized in A/D converter 762 and provided to a processor. That processor may then scale the measured value based on the resistive voltage divider established by resistors R3 and R4 to compute the voltage difference between WIRE2 and the common reference potential.

As with other embodiments, information on the values of resistors R3 and R4 may be determined from rated values of the resistors or parameters of construction of the components used to construct the resistors or by measurement.

In some embodiments, physically positioning a tap on a distributed resistive element to yield a sufficiently small voltage at tap 770 may increase manufacturing costs or pose other challenges. In the embodiment illustrated in FIG. 7B, tap 770 is positioned from the end of the distributed resistive element by a distance that simplifies manufacture of the distributed resistive element, but yields a voltage at tap 770 that might saturate components in measurement circuitry 740B. In this embodiment, a secondary resistive voltage divider, formed by resistors R5 and R6, is included as an input stage to measurement circuitry 740 B. The secondary resistive divider decreases the voltage measured at tap 770 before it is supplied as an input to operational amplifier 752.

In this example, operational amplifier 752 is configured as a buffer amplifier, providing unity gain. Though, it should be appreciated that operational amplifier 752 may have any suitable gain. The output of operational amplifier 752 is provided to A/D converter 762, which produces a digital representation of the measured voltage. That digital representation may then be provided to a process or in a computation to determine the voltage between WIRE2 and the common reference voltage.

In the example illustrated in FIG. 7B, the computation may entail scaling the measured voltage by a value dependent on the secondary voltage divider provided by resistors R5 and R6 and the primary voltage divider provided by resistors R3 and R4. As previously described, information about the values of resistors R3, R4, R5 and R6 may be determined in any suitable way. These value information relating to resistors R3 and R4, for example, may be determined at the time of construction of the distributed resistive element. This value information may take the form of measuring or computing the ratio of the resistive voltage divider created by those resistors. Likewise, value information for resistors R5 and R6 may be determined at the time of the construction of measurement circuitry 740B by measuring or computing the ratio of the resistive voltage divider created by those resistors.

In some embodiments in which the accuracy of voltage measurements depends on values or ratios of resistive elements, value information may be periodically updated after a sensor unit is deployed. This updating may take the form of a field calibration. Such calibration may be performed at periodic intervals or may be performed in response to changing conditions, such as temperature. Though, in some embodiments, stable components or stable construction techniques may be used to reduce the need or frequency of performing such a calibration.

For example, in the embodiment illustrated in FIG. 7B, voltage measurements depend on the ratio of resistive elements R3 and R4 and separately on the ratio of resistive elements R5 and R6. In this scenario, resistive elements R3 and R4, because they are formed from a single distributed resistive element, may have the same construction and will be exposed to the same environmental conditions. Therefore resistors R3 and R4 should exhibit comparable stabilities. As a result, if the value of resistor R3 changes in response to temperature or other environmental conditions, the value of resistor R4 likely will change proportionately, thereby maintaining the ratio used in computing a voltage measurement. Similarly, resistors R5 and R6 may be similar components and may be mounted similarly within a measurement unit. As a result, these components may be exposed to similar environmental conditions and should exhibit similar stabilities. As a result, ratio based on resistors R5 and R6 used in computing a voltage measurement may be stable, leading to accurate voltage measurements.

Turning to FIG. 8, an example of a distributed resistive element configured with a tap is provided. FIG. 8 shows an end of resistive element 800 configured with a connector 820 for connection to a sensor unit. Connector 820 provides a contact defining an end of the resistive element and a tap near that end.

In the embodiment illustrated in FIG. 8, resistive element 800 is formed using techniques as are known in the art for construction of cable assemblies. The assembly formed around a resistive member. In this example, the resistive member is a plastic rod. That rod may be flexible, having, for example, a bend radius such that the rod may be formed into a coil of approximately 1 foot in diameter. Though, it should be appreciated that the mechanical properties of the plastic rod may vary, depending on the intended operating environment of resistive element 800, and the specific mechanical properties are not critical to the invention.

Plastic rod 810 may be imparted with a resistance in any suitable way, including by doping or coating the rod. In the illustrated embodiment, resistive ink is coated on a plastic rod. The ink may be applied to a thickness that provides a suitable resistance, for example, ⅛ of an inch or 3/16 inch. Though, it should be appreciated that the resistance may vary, depending on the intended operating environment of resistive element 800.

Plastic rod 810 may be covered with a jacket 830, as in a conventional cable assembly. The jacket may include a fibrous wrap such as a fiberglass or Kevlar wrap. An outer layer may be resistant to the elements and may provide a protective sheath, as in a conventional cable assembly.

Connector 820 may be attached to an end of a cable in any suitable way. As an example, the protective sheath may be stripped from one end of the cable. The fiberglass coating may be peeled back to expose an end of plastic rod 810. Conductive elements, defining a tap and an end of the resistive element, may then be attached to the exposed end of plastic rod 810.

In this example, conductive element 812 defines the tap and conductive element 816 defines the end of the resistive element. Conductive elements 812 and 816 each have a tubular portion designed to slide over the end of plastic rod 810. These tubular portions may be attached to the resistive coating on plastic rod 810, forming connections to the resistive element.

Any suitable mechanism may be used to form the connection between conductive elements 812 and 816 and the resistive coating on plastic rod 810. For example, the tubular portions may be deformed, such as by crimping, to engage plastic rod 810. Alternatively or additionally, an adhesive may be used to secure conductive elements 812 and 816. The adhesive, for example, may be epoxy 832, which may be conductive or nonconductive.

Regardless of the manner in which conductive elements 812 and 816 are connected to plastic rod 810, spacer 814 may be inserted between conductive elements 812 and 816 to establish spacing between the conductive elements. When resistive element 800 is used with measurement circuitry as illustrated in FIG. 7B, the length of spacer 814, in combination with the resistance per unit length of plastic rod 810, may establish the value of resistor R4. Accordingly, spacer 814 may have a length selected to provide a desired value of resistor R4. As a specific example, spacer 814 may have a length of approximately one quarter of an inch.

Spacer 814 may be constructed in any suitable way. Spacer 814, for example, may be made of an insulative material, such as rubber. Spacer 814 may be attached to plastic rod 810. Alternatively or additionally, spacer 814 may be tubular with dimensions allowing it to slide over plastic rod 810. Spacer 814 may be captured between the tubular portions of conductive elements 812 and 816.

Each of the conductive elements 812 and 816 includes a projecting portion, 822 and 824, respectively. Projecting portions 822 and 824 extend to connector 820, where they serve as conductive contacts. Mating contacts from a complementary connector on a sensor unit (or other component to which distributed resistive element 800 is connected) may make electrical contact with projecting portions 822 and 824. When resistive element 800 is used in an embodiment as illustrated in FIG. 7B, projecting portion 824 may serve as the common terminal for connector 820. Projecting portion 822 creates a terminal at which a line voltage may be measured.

For robustness, the end of resistive element 800 may be overmolded with plastic or other material to encapsulate the tubular portions of conductive elements 812 and 816. The overmolding operation may also be used to form the body of connector 820, with projecting portions 822 and 824 exposed from a mating face of connector the 20.

The fiberglass coating that was peeled back to expose the end of plastic rod 810 may also be captured in the overmold, thereby securing connector 820 to the rest of the cable assembly. Though, any suitable techniques, including those known in the art of cable assembly, may be used to secure cable 822 plastic rod 810.

FIG. 8 provides an example of techniques that may be used to manufacture a tapped resistive element. In distributed resistive element 800, the resistive portions on both sides of the tap are formed of similar materials. Accordingly, the ratio of the resistive voltage divider formed by measuring a voltage at the tap of resistive element 800 with respect to the common terminal is stable and is established at the time of manufacture of distributed resistive element 800. Accordingly, in some embodiments, this ratio may be measured at the time of construction of resistive element 800 and provided to a process or processing measurements made using resistive element 800.

Having thus described several aspects of at least one embodiment of this invention, it is to be appreciated that various alterations, modifications, and improvements will readily occur to those skilled in the art.

For example, embodiments are described in connection with a power distribution system used to deliver power from generation facilities to consumers of that power. However, the techniques described herein may be applied to transmission and distribution conductors in any other suitable setting. For example, techniques described herein may be used to obtain measurements of electrical properties of power lines used by the railway and streetcar industries or of high-voltage conductors used in subway systems.

Also, it should be appreciated that FIG. 8 illustrates a specific technique for terminating a distributed resistive element at an end configured to connect to a sensor unit. Resistive elements constructed in other ways may be terminated to provide a tap and a distal connection point. For example, a tap may be incorporated into a construction as illustrated in FIG. 3A by making a connection to a trace between two of the resistors.

As yet another example, it should be appreciated that the measurement techniques described herein are exemplary and not limiting. Though measurements are described as being made based on ratios of resistances, in some embodiments the actual value of a distributed resistive element may be determined and used in computing a voltage measurement. When the actual value of the resistance of the distributed resistive element is known, current through the distributed resistive element may be measured. Based on this current measurement and known resistive value, a voltage drop across the resistive element may be determined. This voltage drop may be added to measured voltage between the end of the distributed resistive element and a point in the power distribution system where voltage is to be measured.

Such alterations, modifications, and improvements are intended to be part of this disclosure, and are intended to be within the spirit and scope of the invention. Further, though advantages of the present invention are indicated, it should be appreciated that not every embodiment of the invention will include every described advantage. Some embodiments may not implement any features described as advantageous herein. Accordingly, the foregoing description and drawings are by way of example only.

The above-described embodiments of the present invention can be implemented in any of numerous ways. For example, the embodiments may be implemented using hardware, software or a combination thereof. When implemented in software, the software code can be executed on any suitable processor or collection of processors, whether provided in a single computer or distributed among multiple computers. Such processors may be implemented as integrated circuits, with one or more processors in an integrated circuit component. Though, a processor may be implemented using circuitry in any suitable format.

Further, it should be appreciated that a computer may be embodied in any of a number of forms, such as a rack-mounted computer, a desktop computer, a laptop computer, or a tablet computer. Additionally, a computer may be embedded in a device not generally regarded as a computer but with suitable processing capabilities, including a Personal Digital Assistant (PDA), a smart phone or any other suitable portable or fixed electronic device.

Also, a computer may have one or more input and output devices. These devices can be used, among other things, to present a user interface. Examples of output devices that can be used to provide a user interface include printers or display screens for visual presentation of output and speakers or other sound generating devices for audible presentation of output. Additional output devices may include other operational support systems used by a utility to monitor and control their network. Examples of the uses of output from this system could be control of voltage regulators, control of capacitor banks, power consumption data for billing systems, output into outage management systems, or output into fault location isolation and restoration (FLIR) systems. Interfaces into these other operational support systems may include proprietary data interfaces or industry standard protocols such as DNP-3 or IEC 61850. Examples of input devices that can be used for a user interface include keyboards, and pointing devices, such as mice, touch pads, and digitizing tablets. As another example, a computer may receive input information through speech recognition or in other audible format.

Such computers may be interconnected by one or more networks in any suitable form, including as a local area network or a wide area network, such as an enterprise network or the Internet. Such networks may be based on any suitable technology and may operate according to any suitable protocol and may include wireless networks, wired networks or fiber optic networks.

Also, the various methods or processes outlined herein may be coded as software that is executable on one or more processors that employ any one of a variety of operating systems or platforms. Additionally, such software may be written using any of a number of suitable programming languages and/or programming or scripting tools, and also may be compiled as executable machine language code or intermediate code that is executed on a framework or virtual machine.

In this respect, the invention may be embodied as a computer readable storage medium (or multiple computer readable media) (e.g., a computer memory, one or more floppy discs, compact discs (CD), optical discs, digital video disks (DVD), magnetic tapes, flash memories, circuit configurations in Field Programmable Gate Arrays or other semiconductor devices, or other tangible computer storage medium) encoded with one or more programs that, when executed on one or more computers or other processors, perform methods that implement the various embodiments of the invention discussed above. As is apparent from the foregoing examples, a computer readable storage medium may retain information for a sufficient time to provide computer-executable instructions in a non-transitory form. Such a computer readable storage medium or media can be transportable, such that the program or programs stored thereon can be loaded onto one or more different computers or other processors to implement various aspects of the present invention as discussed above. As used herein, the term “computer-readable storage medium” encompasses only a computer-readable medium that can be considered to be a manufacture (i.e., article of manufacture) or a machine. Alternatively or additionally, the invention may be embodied as a computer readable medium other than a computer-readable storage medium, such as a propagating signal.

The terms “program” or “software” are used herein in a generic sense to refer to any type of computer code or set of computer-executable instructions that can be employed to program a computer or other processor to implement various aspects of the present invention as discussed above. Additionally, it should be appreciated that according to one aspect of this embodiment, one or more computer programs that when executed perform methods of the present invention need not reside on a single computer or processor, but may be distributed in a modular fashion amongst a number of different computers or processors to implement various aspects of the present invention.

Computer-executable instructions may be in many forms, such as program modules, executed by one or more computers or other devices. Generally, program modules include routines, programs, objects, components, data structures, etc. that perform particular tasks or implement particular abstract data types. Typically the functionality of the program modules may be combined or distributed as desired in various embodiments.

Also, data structures may be stored in computer-readable media in any suitable form. For simplicity of illustration, data structures may be shown to have fields that are related through location in the data structure. Such relationships may likewise be achieved by assigning storage for the fields with locations in a computer-readable medium that conveys relationship between the fields. However, any suitable mechanism may be used to establish a relationship between information in fields of a data structure, including through the use of pointers, tags or other mechanisms that establish relationship between data elements.

Various aspects of the present invention may be used alone, in combination, or in a variety of arrangements not specifically discussed in the embodiments described in the foregoing and is therefore not limited in its application to the details and arrangement of components set forth in the foregoing description or illustrated in the drawings. For example, aspects described in one embodiment may be combined in any manner with aspects described in other embodiments.

Also, the invention may be embodied as a method, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

What is claimed is:

1. A system for measuring electrical properties of a power line comprising a first wire and a second wire, the system comprising:
a sensor unit configured for connection to the first wire; and
an elongated resistive element comprising a first end configured for connection to the sensor unit and a second end configured for connection to the second wire, the elongated resistive element having a distributed resistance.

2. The system of claim 1, wherein:
the sensor unit comprises a voltage sensor configured to measure a voltage difference between the first end of the resistive element and the first wire.

3. The system of claim 1, wherein:
the first end comprises a termination comprising a tap connection point and a distal connection point.

4. The system of claim 3, wherein:
the elongated resistive element comprises:
a rod having an end;
a resistive coating on the rod;
a first conductive element attached to the rod a first distance from the end;
a second conductive element attached to the rod a second distance from the end, the second distance being greater than the first distance,
wherein the tap connection point is formed by the second conductive element.

5. The system of claim 4, wherein:
the elongated resistive element further comprises an insulating spacer between the first conductive element and the second conductive element.

6. The system of claim 1, wherein:
the second end of the elongated resistive element is configured for connection to the second wire via a clamp.

7. The system of claim 1, wherein the distributed resistance is 50 MOhms/5 feet.

8. The system of claim 1, wherein the elongated resistive element has a resistance of 50 MOhms and a length of 5 feet.

9. The system of claim 1, wherein the elongated resistive element comprises a resistive core and an insulative jacket.

10. The system of claim 1, wherein the elongated resistive element comprises a plastic/carbon fiber extrusion.

11. The system of claim 1, wherein the elongated resistive element comprises:
a flexible base; and
a plurality of discrete resistors connected in series attached to the flexible base.

12. The system of claim 11, wherein:
the flexible base comprises conductive traces; and
the plurality of discrete resistors comprises surface mount resistors soldered to the conductive traces.

13. The system of claim 1, wherein the elongated resistive element comprises a plurality of segments, the plurality of segments comprising at least a rigid, straight segment and at least one bent segment coupled in series with the straight segment.

14. The system of claim 14, wherein the straight segment is coupled in series with the bent segment via a threaded coupling.

15. The system of claim 13, wherein the at least one bent segment is flexible.

16. The system of claim 1, wherein the elongated resistive element is longer than 4 feet.

17. The system of claim 16, wherein the distributed resistance is in excess of 5 MOhm/foot.

18. The system of claim 1, wherein the first wire is a voltage-carrying wire and the second wire is a neutral wire.

19. The system of claim 1, wherein the first wire is a voltage-carrying wire and the second wire is a voltage-carrying wire.

20. A resistive element adapted for connecting a sensor unit between a first wire and a second wire of a power line, the resistive element comprising:
an elongated member having a length of at least 3 feet, the elongated member having a first end and a second end,
wherein the elongated member has an average resistance of at least 1 MOhm/foot and a resistance distribution variation of less than +1−40% between any two 12-inch segments of the elongated member.

21. The resistive element of claim 20, further comprising:
a connector coupled to the first end, the connector being configured for connection to a wire of the power line.

22. The resistive element of claim 21, wherein:
the elongated member comprises:
a flexible substrate comprising conductive traces; and
a plurality of resistors attached to the conductive traces.

23. The resistive element of claim 22, wherein:
each resistor of the plurality of resistors has a resistance greater than 250 KOhms and resistors in the plurality of resistors are spaced at an average pitch of less than 0.5 inches.

24. The resistive element of claim 23, further comprising an insulative sheath.

25. The resistive element of claim 20, wherein:
the elongated member comprises plastic doped to provide a resistance between 1 MOhm/foot and 10 MOhm/foot.

26. The resistive element of claim 25, wherein the plastic is doped with carbon.

27. The resistive element of claim 20, wherein:
the elongated member comprises an insulative material with fillers in a quantity to provide a resistance between 1 MOhm/foot and 10 MOhm/foot.

28. The resistive element of claim 20, wherein:
the elongated member comprises a substrate and a layer of partially conductive ink disposed on the substrate.

29. The resistive element of claim 20, wherein:
the elongated element dissipates less than 35 Watts when connected between the first wire and the second wire and the power line carries a voltage of at least 35 KVolts.

30. The resistive element of claim 20, wherein:
the elongated member is flexible.

31. The resistive element of claim 30 wherein the elongated member comprises a rigid portion and at least one flexible portion.

32. The resistive element of claim 20, further comprising:
a coupling for connection to a sensor unit attached to the second end.

33. The resistive element of claim 32, wherein:
the coupling comprises a tap connection point a distal connection point.

34. The resistive element of claim 33, wherein:
the elongated member comprises:
a rod having an end;
a resistive coating on the rod;
a first conductive element attached to the rod a first distance from the end;
a second conductive element attached to the rod a second distance from the end, the second distance being greater than the first distance,
wherein the tap connection point is formed by the second conductive element.

35. The resistive element of claim 34, wherein:
the first conductive element comprises a first tubular portion and a first projecting portion;
the second conductive element comprises a second tubular portion and a second projecting portion,
wherein:
the first projecting portion forms the distal connection point; and
the second projecting portion comprises the tap connection point.

36. A method of operating a sensor unit coupled to power line, the power line comprising a hot wire carrying in excess of 10,000 volts and another wire, the method comprising:
measuring a voltage between the hot wire and the other wire with a voltage sensor in the sensor unit;
measuring a current flow through a resistive element connected in series with the sensor unit between the hot wire and the other wire; and
adjusting the voltage measurement based on the measured current through the resistive element.

37. The method of claim 36, further comprising:
installing the sensor unit and the resistive element while the power line is carrying in excess of 10,000 Volts.

38. The method of claim 36, wherein:
the resistive element has a length in excess of 4 feet.

39. The method of claim 36, wherein:
the resistive element is flexible.

40. The method of claim 36, wherein the second wire is a neutral wire.

41. The method of claim 36, wherein the second wire is a hot wire.
